(19) United States
(12) Patent Application Publication
(10) Pub. No.: US 2011/0115472 A1
(43) Pub. Date: May 19, 2011

(54) CONTROL CIRCUIT FOR CURRENT DETECTION

(76) Inventors: Yuh-Min Lin, San Ramon, CA (US); Ho-Yi Shih, Taipei City (TW)

(21) Appl. No.: 12/683,788

(22) Filed: Jan. 7, 2010

(30) Foreign Application Priority Data
Nov. 17, 2009 (TW) 98138934

(51) Int. Cl. G01R 19/00

(52) U.S. Cl. 324/123 R

(57) ABSTRACT

A control circuit for current detection is disclosed. The control circuit outputting an output current to a power device comprises at least one first Field Effect Transistor (FET) coupled to the positive input terminal of an operational amplifier. The first FET is coupled to the power device through two voltage terminals, wherein the output current is passed through the first FET. The control circuit further comprises at least one second FET coupled to the first FET and the negative input terminal of the first operational amplifier, utilizing the virtual-short characteristic of the first operational amplifier to form a current mirror with the first FET, and copying the output current to generate a copy current by a scale whereby the output current is detected by the copy current. The invention detects the output current without consuming additional power so as to measure the power consumption for the power device.

### BACKGROUND OF THE INVENTION

1. Field of the Invention

The present invention relates to a control circuit, particularly to a control circuit for current detection.

2. Description of the Related Art

Power over Ethernet (PoE) is a system, which obtains power through cables. In other words, when users' internet equipments are provided with PoE, the internet equipments are connected to the cables to work normally without coupling to a plug. The above-mentioned function of PoE is very convenient.

As shown in FIG. 1, in general, PoE 10 comprises Power Sourcing Equipment (PSE) 12 and Power Device (PD) 14. PSE 12 and PD 14 are both used together otherwise PoE 10 won't function properly. PSE 12 has to detect its output current to tell the upper system the power consumption for PD 14 and prevent short-circuiting. Therefore, in the traditional technology, a control circuit 16 turns on a transistor 18 such that current flows to the PD 14 through the transistor 18. A power resistor 20, connected with the transistor 18 in series, is used to detect the output current output from PSE 12. Due to the fact that the value of the power resistor 20 is between 0.1 ohm and 0.47 ohm, it is not easy to fabricate the power resistor 20 during IC process. Thus, an external power resistor needs to be installed. However, the power consumption of the external power resistor reduces the working efficiency of PSE.

Furthermore, when the transistor 18 is turned on, all power noise is transmitted to PD 14 through the cables 22. At the same time, the signals transmitted on the cables 22 will be distorted by interference from the power noise.

In view of the problems and shortcomings of the prior art, the present invention provides a method and a control circuit for current detection, so as to solve the afore-mentioned problems of the prior art.

### SUMMARY OF THE INVENTION

An objective of the present invention is to provide a control circuit for current detection. The control circuit comprises an operational amplifier disposed between two transistors whereby the transistor copies the output current output from the control circuit. The output current is detected without consuming additional power and the operational amplifier is turned off in order to save power when detection of the output current isn't required.

Another objective of the present invention is to provide a control circuit for current detection, which comprises a capacitor and an operational amplifier disposed between a positive voltage terminal thereof and a negative voltage terminal thereof. When power noise is generated at the positive voltage terminal, the capacitor transmits the power noise from the positive voltage terminal to the negative voltage terminal by utilizing the virtual short characteristic for a position between a positive input terminal and a negative input terminal of the operational amplifier whereby a voltage drop of the power noise between the positive voltage terminal and the negative voltage terminal is eliminated. Besides, the capacitor can avoid generation of incorrect signals.

To achieve the abovementioned objectives, the present invention provides a control circuit for current detection, which is installed inside Power Sourcing Equipment (PSE) of Power over Ethernet (PoE), and which is coupled to Power Device (PD) to detect an output current output from PSE to PD. The control circuit comprises at least one first Field Effect Transistor (FET) coupled to the positive input terminal of a first operational amplifier and the output terminal of a second operational amplifier, wherein the first FET is coupled to PD through a positive voltage terminal and a negative voltage terminal. The negative voltage terminal is coupled to the negative input terminal of the second operational amplifier. The positive voltage terminal is coupled to the positive input terminal of the second operational amplifier through a capacitor. The output current is passed through the first FET. Also, the positive voltage terminal is coupled to a voltage source. When an input voltage provided by the voltage source generates a power noise at the positive voltage terminal, the capacitor transmits the power noise to the negative voltage terminal by utilizing a virtual short characteristic for a position between the positive input terminal and the negative input terminal of the second operational amplifier whereby a voltage drop of the power noise between the positive voltage terminal and the negative voltage terminal is eliminated. Furthermore, the first FET and the negative input terminal of the first operational amplifier are coupled to at least one second FET, wherein the second FET forms a current mirror with the first FET by utilizing the virtual short characteristic for a position between the positive input terminal and the negative input terminal of the first operational amplifier. The second FET copies output current to generate a copy current by a scale whereby the output current is detected by the copy current.

Below, the embodiments are described in detail in cooperation with the drawings to make easily understood the characteristics, technical contents and accomplishments of the present invention.

### BRIEF DESCRIPTION OF THE DRAWINGS

FIG. 1 is a diagram schematically showing Power over Ethernet (PoE) of the prior art;

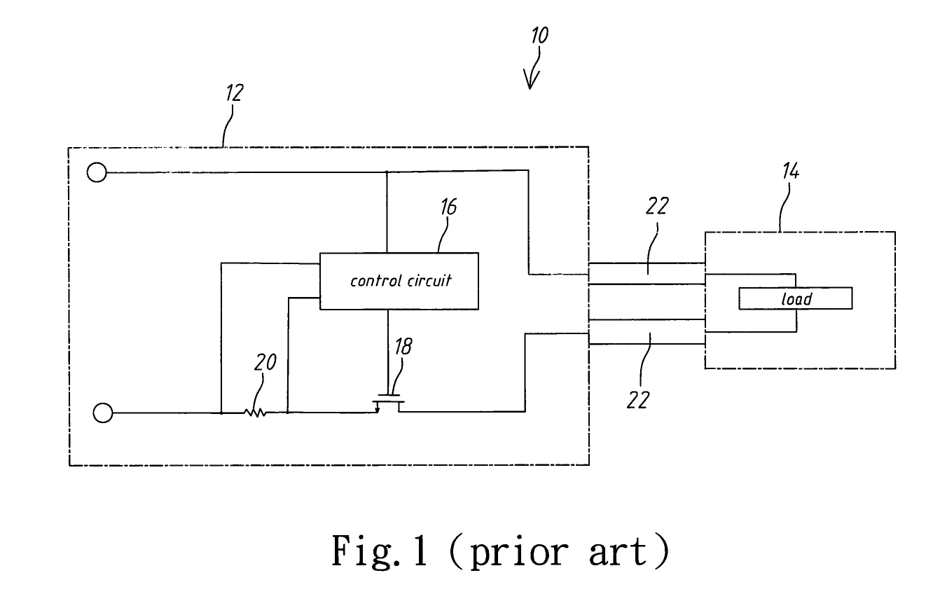

FIG. 2 is a diagram showing a control circuit according to a first embodiment of the present invention; and

FIG. 3 is a diagram showing a control circuit according to a second embodiment of the present invention.

### DETAILED DESCRIPTION OF THE INVENTION

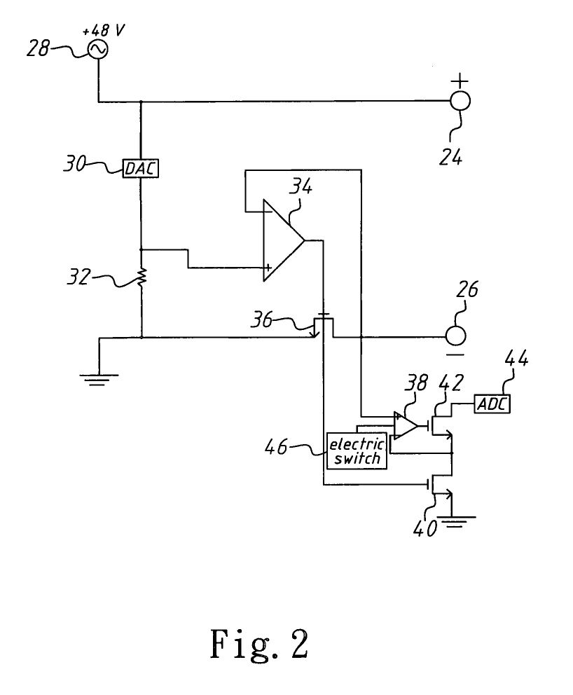

The present invention is applied to Power over Ethernet (PoE). Below is a description of a first embodiment. Refer to FIG. 2. The control circuit for current detection of the present invention which is installed inside Power Sourcing Equipment (PSE) of PoE, is coupled to Power Device (PD) to detect an output current output from PSE to PD.

The control circuit for current detection comprises a positive voltage terminal 24 and a negative voltage terminal 26. The positive voltage terminal 24 and the negative voltage terminal 26 are respectively coupled to PD. The positive voltage terminal 24 coupled to a voltage source 28 providing a direct-current (DC) input voltage of 48 V is used to output the output current. The voltage source 28 is coupled to a current mode digital-to-analog converter (DAC) 30. The current mode digital-to-analog converter (DAC) 30 is coupled to a side of a resistor 32. The resistor 32 with another side thereof is separately coupled to the source of at least one first N-channel Metal Oxide Semiconductor Field Effect Transistor (NMOSFET) 36 and a ground terminal. The drain of the first NMOSFET 36 is coupled to negative voltage terminal 26. The current mode DAC 30 receives an input voltage provided by the voltage source 28 to generate a constant voltage of 0.4 V at a node between the resistor and the current mode DAC. The embodiment is exemplified by the one first NMOSFET 36.

The control circuit of the present invention further comprises a first operational amplifier 34 with a negative input terminal thereof coupled to the drain of the first NMOSFET 36, output terminal thereof coupled to the gate of the first NMOSFET 36 and a positive input terminal thereof coupled to the resistor 32 and the current mode DAC 30. The first operational amplifier 34 receives the constant voltage to turn on the first NMOSFET 36. Thus, after the control circuit outputs the output current from the positive voltage terminal 24 to PD, the output current will flow back to the negative voltage terminal 26 and pass through the first NMOSFET 36.

The gate of the first NMOSFET 36 is coupled to the gate of at least one second NMOSFET 40. The embodiment is exemplified by the one second NMOSFET 40. The drain and the source of the second NMOSFET 40 are separately coupled to a negative input terminal of a second operational amplifier 38 and the ground terminal. A positive input terminal of the second operational amplifier 38 is coupled to the drain of the first NMOSFET 36. From FIG. 2, it is known that the drain voltage of the second NMOSFET 40 is the same as the drain voltage of the first NMOSFET 36 by utilizing the virtual short characteristic for a position between the positive input terminal and the negative input terminal of the second operational amplifier 38. Thus, the second NMOSFET 40 forms a current mirror with the first NMOSFET 36. And the second NMOSFET 40 can copy the output current accurately, so as to generate a copy current by a scale.

To save current consumption the device specification for the first NMOSFET 36 and the second NMOSFET 40 is adjusted. For example, adjusting the ratio of the length and width of the channel whereby the scale is greater than 0 and less than 1, or the scale is greater than 0 and equal to 1. Also, when the first NMOSFET 36 is a plurality of first NMOSFETs and the second NMOSFET 40 is a plurality of second NMOSFETs, the device specifications for the first NMOSFETs 36 and the second NMOSFETs 40 are equal and the number of the second NMOSFETs 40 is less than that of the first NMOSFETs 36. Thus, the scale is greater than 0 and less than 1, or the scale is greater than 0 and equal to 1.

The drain of the second NMOSFET 40 is coupled to the source of a third NMOSFET 42. The gate and the drain of the third NMOSFET 42 is separately coupled to the output terminal of the second operational amplifier 38 and a current mode analog-to-digital converter (ADC) 44. The second operational amplifier 38 receives the constant voltage to turn on the third NMOSFET 42 by utilizing the virtual-short of the first operational amplifier 34. After turning on the third NMOSFET 42, the third NMOSFET 42 transmits the copy current generated by the second NMOSFET 40 to the current mode ADC 44, and then the current mode ADC 44 detects the output current through the copy current.

The second operational amplifier 38 is further coupled to an electric switch 46 controlling the switching status of the second operational amplifier 38. When the control circuit doesn't detect the output current, the electric switch 46 turns the second operational amplifier 38 off to save power.

When the voltage source 28 starts to provide DC voltage, the current mode DAC 30 receives an input voltage provided by the voltage source 28 to generate a constant voltage at a node between the resistor and the current mode DAC 30. The positive voltage terminal 24 outputs an output current to PD since the voltage source 28 has begun operating. Next, the first operational amplifier 34 receives the constant voltage to turn on the first NMOSFET 36 whereby the output current transmitted from PD to PSE is passed through the first NMOSFET 36. Since the first NMOSFET 36 is turned on, the second NMOSFET 40 is also turned on. The second NMOSFET 40 can form a current mirror by utilizing the virtual-short theorem of the first NMOSFET 36 and the second NMOSFET 40. Therefore, the second NMOSFET 40 copies the output current to generate a copy current. Because the second operational amplifier 38 has already received the constant voltage by utilizing the virtual-short theorem of the first NMOSFET 36 to turn on the third NMOSFET 42 at this time, the third NMOSFET 42 transmits the copy current to the current mode ADC 44. Then, the current mode ADC 44 can detect the output current without consuming additional power.

When the control circuit doesn't detect the output current, the electric switch 46 turns the second operational amplifier 38 off. Thus, the third NMOSFET 42 and the second NMOSFET 40 are turned off in turn. In other words, the third NMOSFET 42, the second NMOSFET 40, and the current mode ADC 44 all suspend operation, so as to save power.

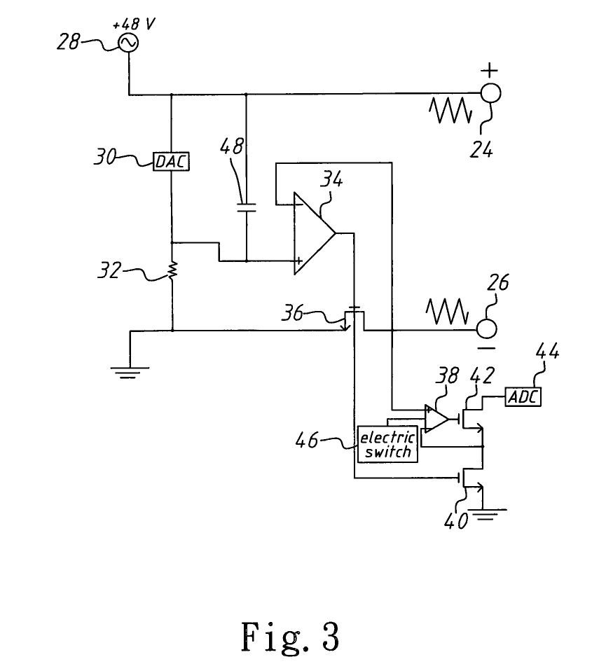

Refer to FIG. 3. Below is a description of a second embodiment. The second embodiment is different from the first embodiment in that the control circuit further comprises a capacitor 48 coupled to the positive input terminal of the first operational amplifier 34 and the voltage source 28. Because the input voltage provided by the voltage source 28 generates a power noise at the positive voltage terminal 24, the capacitor 48 transmits the power noise to the negative voltage terminal by utilizing the virtual short characteristic for the position between the positive input terminal and the negative input terminal of the first operational amplifier 34 whereby a voltage drop of the power noise between the positive voltage terminal 24 and the negative voltage terminal 26 is eliminated. Thus, the capacitor 48 can avoid generation of incorrect signals to affect the operation for the next stage circuit.

In conclusion, the present invention comprises an operational amplifier disposed between two transistors whereby the transistor copies the output current output from the control circuit, and then the output current is detected without consuming additional power. In addition, the present invention can turn off the operational amplifier to save power when detection of the output current is not required.

The embodiments described above are only to exemplify the present invention but not to limit the scope of the present invention. Therefore, any equivalent modification or variation according to the shape, structures, characteristics and spirit disclosed in the present invention is to be also included within the scope of the present invention.

What is claimed is:

1. A control circuit for current detection, which is installed inside a Power Sourcing Equipment (PSE) of a Power over Ethernet (PoE), and which is coupled to a Power Device (PD) to detect an output current output from the PSE to the PD, comprising:
at least one first Field Effect Transistor (FET) coupled to the PD through a negative voltage terminal and a positive voltage terminal which is coupled to a voltage source, wherein the output current is passed through the first FET;
a first operational amplifier with a positive input terminal thereof coupled to the first FET; and
at least one second FET coupled to the first FET and a negative input terminal of the first operational amplifier utilizing a virtual short characteristic for a position between the positive input terminal and the negative input terminal of the first operational amplifier to form a current mirror with the first FET, and copying the output current to generate a copy current by a scale whereby the output current is detected by the copy current.

2. The control circuit for current detection according to claim 1, wherein a gate, a drain, and a source of the first FET are separately coupled to the positive voltage terminal, the negative voltage terminal, and a ground terminal respectively; the positive input terminal of the first operational amplifier is coupled to the drain of the first FET; a gate, a drain, and a source of the second FET are separately coupled to the gate of the first FET, the negative input terminal of the first operational amplifier, and the ground terminal respectively.

3. The control circuit for current detection according to claim 1, further comprising:
a third FET with a gate thereof coupled to an output terminal of the first operational amplifier and a source thereof coupled to a drain of the second FET, wherein the first operational amplifier turns on the third FET by utilizing an input voltage provided by the voltage source; and
a current mode analog-to-digital converter (ADC) coupled to a drain of the third FET, wherein the third FET transmits the copy current to the current mode ADC to detect the output current.

4. The control circuit for current detection according to claim 3, wherein the first FET, the second FET, and the third FET are all N-channel Metal Oxide Semiconductor Field Effect Transistors (NMOSFETs).

5. The control circuit for current detection according to claim 1, further comprising:
an electric switch coupled to the first operational amplifier and controlling a switching status of the first operational amplifier.

6. The control circuit for current detection according to claim 1, further comprising:
a current mode digital-to-analog converter (DAC) coupled to the voltage source;
a resistor with two side thereof separately coupled to the current mode DAC and a source of the first FET, wherein the current mode DAC receives an input voltage provided by the voltage source to generate a constant voltage at a node between the resistor and the current mode DAC; and
a second operational amplifier with a negative input terminal thereof coupled to a drain of the first FET, an output terminal thereof coupled to a gate of the first FET, and a positive input terminal thereof coupled to the resistor and the current mode DAC, wherein the second operational amplifier receives the constant voltage to turn on the first FET whereby the output current is passed through the first FET.

7. The control circuit for current detection according to claim 6, further comprising:
a capacitor coupled to the positive input terminal of the second operational amplifier and the voltage source; wherein when an input voltage provided by the voltage source generates a power noise at the positive voltage terminal, the capacitor transmits the power noise to the negative voltage terminal by utilizing a virtual short characteristic for a position between the positive input terminal and the negative input terminal of the second operational amplifier whereby a voltage drop of the power noise between the positive voltage terminal and the negative voltage terminal is eliminated.

8. The control circuit for current detection according to claim 1, wherein device specifications for the first FET and said second FET are equal; and a number of the second FET is less than that of the first FET.

9. The control circuit for current detection according to claim 1, wherein the scale is greater than 0 and less than 1 or the scale is greater than 0 and equal to 1.

10. The control circuit for current detection according to claim 1, wherein the positive voltage terminal outputs the output current by utilizing an input voltage provided by the voltage source and then the output current flows back to the negative voltage terminal; and the input voltage is a direct-current (DC) voltage.
